(19) United States
(12) Patent Application Publication
(10) Pub. No.: US 2013/0031895 A1
(43) Pub. Date: Feb. 7, 2013

(54) HEAT EXCHANGER FOR THERMOELECTRIC GENERATORS

(71) Applicant: Patrick Glaser, Stuttgart (DE)

(72) Inventor: Patrick Glaser, Stuttgart (DE)

(21) Appl. No.: 13/576,345

(22) PCT Filed: Dec. 20, 2010
(86) PCT No.: PCT/EP2010/070181

§ 371 Date: Oct. 16, 2012

(30) Foreign Application Priority Data
Feb. 1, 2010 (DE) 10 2010 001 417.6

(51) Int. Cl. H01L 35/30; H01L 35/02; F01N 5/02; F28D 15/00

(52) U.S. Cl. 60/320; 165/48.1; 165/104.11; 136/242; 136/224

(57) ABSTRACT

A heat exchanger for thermoelectric generators having at least two channels for a cooling medium and at least one channel for a heating medium, the at least one channel for the heating medium being equipped with ribs in the inner region. These ribs are mounted at a number of ribs that increases in the heating flow direction which, among other things, contributes to a more efficient utilization and a comparability of the heat flow.

### FIELD OF THE INVENTION

The present invention relates to a heat exchanger for thermoelectric generators.

### BACKGROUND INFORMATION

The exhaust gas heat produced by motor vehicles which, depending on the model, may amount to up to 35%, is frequently given off to the environment unused. An effective utilization of this heat energy would, however, bring along with it a reduction in fuel consumption.

One possibility of utilizing this exhaust gas heat is thermoelectric generators (TEG). In the free ends of two conductors connected to each other, in response to a temperature difference along the conductors, an electric voltage is produced. Devices for producing energy from the exhaust gas heat are believed to be understood and discussed in German document DE 10 2008 005 334 A1, for example.

For better utilization of the exhaust-gas energy, flow channels, through which the heat-dissipating fluid flows, partially have stiffening devices in the form of ribs, which are normally mounted at equidistant distances from one another. These ribs enlarge the surface of the flow channel and thus assure better heat transmission between heat-dissipating fluid and the flow channel.

At this time, no mass-produced applications exist for thermoelectric generators for exhaust gas heat recovery. Experimental carriers for these applications are usually unribbed or continuously ribbed flat channels.

Unribbed channels have poor heat transfer coefficients, and prevent efficient utilization of the exhaust-gas energy.

High heat flow densities are able to be implemented in ribbed channels, whereby the installation space required and the number of thermoelectric generators required may be reduced. However, in typical exhaust gas applications, continuous ribbing leads to a continual reduction in the TEG hot side temperature in the flow direction, resulting from heat transfer coefficients that change only slightly in the flow direction, on the basis of which the TEG hot side temperature continually follows the greatly dropping exhaust-gas temperature.

German document DE 10 2007 062 826 A1 discusses a heat exchanger for a motor vehicle. The laid-open document shows an heat exchanger having rib elements which are situated at different density, whereby an effect on the heat transfer takes place.

For the purpose of weight savings and cost savings, as well as for heat flow maximization, in the area of the entry of a first fluid, the rib elements have a particularly dense arrangement, in order to support the greatest heat transfer, occurring there, to the second fluid.

### SUMMARY OF THE INVENTION

In order to make as large a part of the thermal energy available, that is contained in the exhaust gas, particularly that of an internal combustion engine of a motor vehicle, an heat exchanger according to the present invention, for thermoelectric generators (TEG), is provided with ribs to enlarge the surface of a flow channel, and with that, to produce a better heat transfer. According to the exemplary embodiments and/or exemplary methods of the present invention, these ribs are not applied equidistantly to one another, but rather at increasing rib density, adapted to the heat flow to be expected.

The heat exchanger proposed according to the exemplary embodiments and/or exemplary methods of the present invention, having an adapted rib density for thermoelectric generators, makes possible an effective exhaust gas heat recapture, which in turn makes it possible to capture electric current from this otherwise unused energy, which is able to be utilized for different systems of the passenger car, and thus contributes decisively to saving fuel, reduces the CO₂ emission and drops pollutant emissions. Thereby thermoelectric generators improve the energy efficiency, environmental compatibility and economy, and at the same time are robust, maintenance-free and adaptable to various fields of application.

In typical exhaust gas applications, continuous ribbing would lead to a continual reduction in the TEG hot side temperature in the flow direction, since the heat transfer coefficients change only slightly in the flow direction and the TEG hot side temperature continually follows the greatly dropping exhaust gas temperature. The result is that the thermoelectric generators work inefficiently in the last rows of the heat exchanger because of the slight temperature difference, which lowers the efficiency, and because of the low heat flow density. Above all, if the admissible maximum temperature is limited by the TEG material, for example, the wall temperature at the intake of the heat exchanger has to be limited to the admissible maximum temperature, and consequently it lowers the overall available energy. Using the rib density adapted as provided by the exemplary embodiments and/or exemplary methods of the present invention, one is able to achieve a substantially more efficient utilization of the heat flow than when the ribbing is constructed equidistantly.

The increase in the heat transfer by increased rib density is a known physical relationship, but this increase in the rib density takes place in the opposite direction than is known from the related art, where the saving in material is the principal purpose. Such a targeted change in the rib density leads to a comparability of the heat flow, and thus to a temperature profile specified over the entire length of the heat exchanger.

One advantageous comparability of the TEG hot side temperature may be achieved by an increase in the heat transfer in the flow direction. This may be achieved by a subdivision of the longitudinal ribs and an increasing rib density in the flow direction. If a maximum admissible TEG temperature is limiting the TEG hot side temperature at the intake, a higher thermal output of the heat exchanger is able to be achieved by an increasing rib density. This method may be used both for the wavy ribs usual in heat exchangers, such as herringbone ribs, and for flat ribs. Moreover, flat and wavy ribs may be combined. For the same heat transfer, wavy ribs have a lower rib density, and thus a reduced weight, but also lower strength. They consequently have advantages in areas of the heat exchanger in which a high heat transfer is required. In areas having a low heat transfer, more densely packed flat ribs may be used under certain circumstances, if an external prestressing force is applied to the system.

Any number of subdivisions may be introduced, the inclination to fouling deposits, however, say, by soiling caused by substances contained in the heating medium, at the leading edges of the ribs having to be paid attention to. One meaningful subdivision may be made, for instance, by a TEG element-wise subdivision.

A further advantage is an increased overall heat flow. The greater the temperature differences between the conductors, the more current is able to be produced by the thermoelectric generators. The thermoelectric generators work inefficiently in the last rows of the heat exchanger because of the slight temperature difference, and because of the low heat flow density. Above all, if the admissible maximum temperature is limited (for instance, by the TEG material), the wall temperature at the intake of the heat exchanger has to be limited to the admissible maximum temperature, and consequently it lowers the overall available energy. Because of the adapted rib density, a comparability of the temperature difference and the heat flow density is achieved, which contributes to a more efficient utilization of the thermoelectric generators.

An adaptation of the rib density to the heat flow is especially meaningful for the application in thermoelectric generators, since thereby the thermoelectric modules in the longitudinal direction of the exhaust gas perceive similar exhaust gas output, in spite of a reduction in the exhaust-gas temperature. Because of this, active electrical output is generated in the different thermoelectric module rows, which reduces demand on the DC motor controller.

The exemplary embodiments and/or exemplary methods of the present invention are explained below in greater detail on the basis of the drawings.

### BRIEF DESCRIPTION OF THE DRAWINGS

FIG. 1 shows an exemplary layout of a heat exchanger having ribbed heating channels and three rows of thermoelectric generators (TEG) in the flow direction.

FIG. 2 shows an inner-ribbed channel for a heating medium having increasing rib density.

FIG. 3 shows a top view onto a longitudinal section through an inner-ribbed channel for a heating medium in two different embodiment variants: a) flat ribs at rising rib density, and b) flat ribs in rows 1 and 2+wavy ribs in row 3.

FIG. 4a shows a qualitative temperature curve in the flow direction in a TEG heat exchanger at continuous ribbing and limitation by Tmax.

FIG. 4b shows a qualitative temperature curve in the flow direction in a TEG heat exchanger at increasing rib density in the case of three TEG elements.

### DETAILED DESCRIPTION

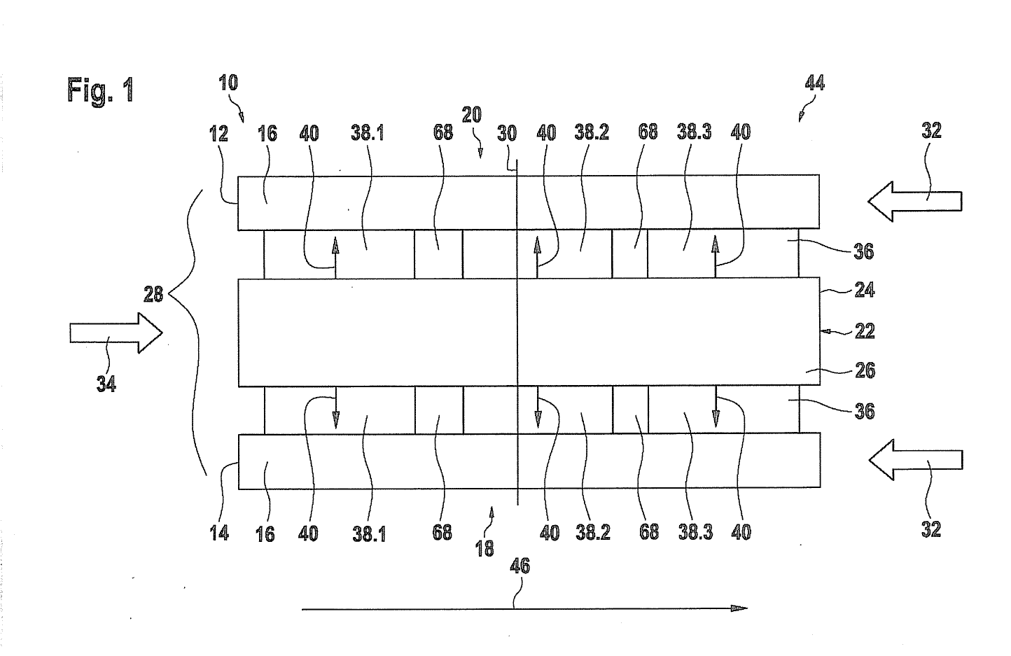

FIG. 1 represents a possible layout of a heat exchanger having ribbed heating channels and three rows of thermoelectric generators (TEG) in the flow direction.

In one possible type of embodiment, a heat exchanger 10 may have two channels 12, 14 for a cooling medium 16 as a heat sink. The one channel 12 for cooling medium 16 runs on a lower side 18 of heat exchanger 10, in this context, and second channel 14 for cooling medium 16 runs on upper side 20 of heat exchanger 10.

In the middle 22 of heat exchanger 10 there is located an additional channel 24 for a heating medium 26, which functions as a heat source.

Channels 12, 14 for cooling medium 16 and channel 24 for a heating medium 26 extend in planes that are parallel to one another and, in the process form a stack 28 having a stack axis 30. As seen along stack axis 30, channels 12, 14 for cooling medium 16 and channel 24 for heating medium 26 are situated alternatingly.

Other combinations of alternating channels 12, 14 for cooling medium 16 and channels 24 for heating medium 26 are also possible.

A fluid giving off heat may be conveyed through channel 24 for heating medium 26, the fluid giving off heat may originate from a waste heat system and, particularly, may be the exhaust gas of an internal combustion engine of a motor vehicle.

A fluid taking up heat is able to flow through channels 12 and 14 for the cooling medium.

Cooling flow direction 32 may be directed opposite to the heating flow direction.

Within heat exchanger 10, between channel 12 for cooling medium 16 and channel 24 for heating medium 26 or between channel 24 for heating medium 26 and channel 14 for cooling medium 16 there is a number of thermoelectric generators 36.

During the operation of heat exchanger 10, channel 24 of heating medium 26 has a hot fluid flowing through it. The heat contained in the fluid flows as heat flow 40 through thermoelectric generators 36 and is taken up by the latter.

Channels 12 and 14 of cooling medium 16 have a cooling fluid flowing through them, which takes up heat flow 40 after it has been conveyed through thermoelectric generators 36.

Because of a different temperature T1 of heating medium 26 and a temperature TO of cooling medium 16, a temperature gradient ΔT is created. Driven by temperature difference ΔT, charge carriers migrate in these semiconductor materials, and an electric current flows.

With the aid of the thermoelectric generators 36, an electric voltage is able to be generated, which is able to be picked off at electric terminals (not shown) of heat exchanger 10. In order to obtain sufficiently high voltages, and thus to increase the electrical output of heat exchanger 10, a plurality of thermoelectric generators 36 may be mounted in heat exchanger 10 between cooling medium 16 and and heating medium 26, on cover plates, and connected in parallel or in series. These thermoelectric generators 36, from now on designated as TEG rows 38.1, 38.2, 38.3, are mounted in heating flow direction 34.

Between channels 12, 14 for cooling medium 16 and channel 24 for heating medium 26, there is in each case at least one air-filled interspace 68, which makes possible a flexible equalization between the individual contact points of TEG rows 38.

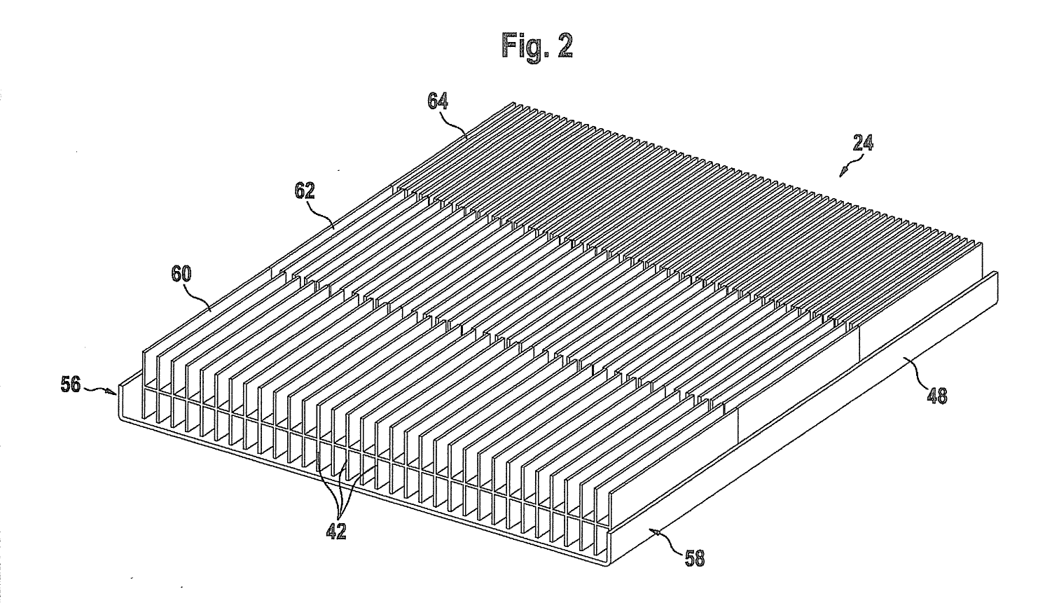

FIG. 2 shows a section of inner-ribbed channels for a heating medium having increasing rib density.

Channel 24 for heating medium 26, enclosed by a channel jacket 48, includes in an inner region 54, a plurality of stiffening devices, which are developed in the form of ribs 42. Ribs 42 may extend from one side 56 of channel 24 for heating medium 26 all the way to opposite side 58 of channel 24 for heating medium 26, in order to maximize the surface of ribs 42, which contributes to an improved heat transfer.

These ribs 42 could also be developed to be continuous (FOOT durch=auch), or in an interrupted manner so as to reduce rigidity.

At least one rib 42 may be connected to channel 24 for heating medium 26 in a continuous material manner or by force locking. Besides a secure and long-lasting fastening, this ensures a particularly good heat transfer between channel 24 for heating medium 26 and the at least one rib 42.

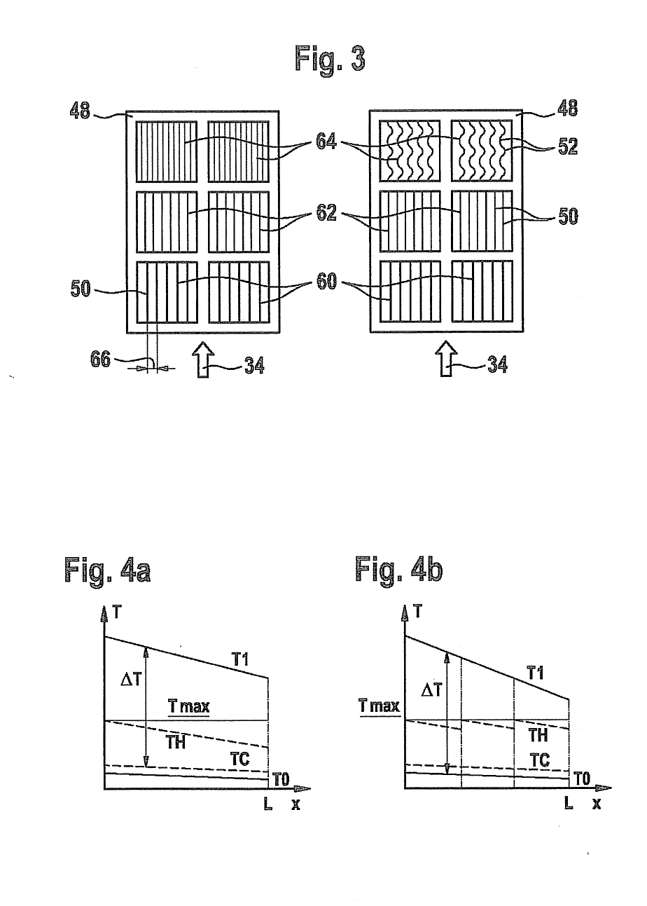

FIG. 3 shows a top view onto a longitudinal section through an inner-ribbed channel for a heating medium in two different embodiment variants, having flat ribs having an increasing rib density in combination with wavy ribs.

The stiffening elements developed as ribs 42 inner region 54 of channel 24 for heating medium 26 may be developed both as wavy ribs 50, for instance herringbone ribs or as flat ribs 52. Any number of subdivisions may be introduced, the inclination to fouling deposits, however, say, by soiling caused by substances contained in the heating medium, at the leading edges of the ribs, having to be paid attention to.

A distance 60 between two ribs 42 decreases in heating flow direction 34 along a heat exchanger length 46. In FIGS. 2 and 3, inner region 54 of channel 24 for heating medium 26 is shown having increasing rib density in heating flow direction 34, in three stages—low rib density 60, medium rib density 62 and high rib density 64.

Because of this increment in ribs 42, an enlarged surface per volume is provided for the exchange of heat of heating medium 26 with cooling medium 16. It is ensured, thereby that temperature gradient ΔT is sufficiently large even at TEG rows 38.3 at a rear end 44 of heat exchanger 10, and that an efficient utilization of heat flow 40 is made possible.

In addition, because of the change in the number of ribs 42, it is assured that the efficiency of the individual TEG rows 38.1, 38.2, 38.3 is approximately constant, in spite of the decrease in temperature T1 of heating medium 26. Because of this, in the different TEG rows 38.1, 38.2, 38.3, a nearly uniform electrical output is generated, which reduces demand on the DC motor controller.

One meaningful subdivision may be made, for instance, by a TEG element-wise subdivision. Therefore, the number of ribs 42 along heat exchanger length 46 increases with each TEG row 38.1, 38.2, 38.3.

Furthermore, flat ribs 52, and wavy ribs 50, as shown in FIG. 3(b) in heat exchanger 10 may be combined for the purpose of comparability of the heat flow and of weight reduction. Wavy ribs 52, at the same heat transfer, have a lower rib density, and thus a reduced weight, but also lower strength. They consequently have advantages in areas of the heat exchanger in which a high heat transfer is required. In areas having a low heat transfer, more densely packed flat ribs 52 may be used under certain circumstances, if an external prestressing force is applied to the system.

In addition, a number of ribs 42, adapted to heat flow 40 at equal heat exchanger output, makes possible a material reduction and thereby also a weight reduction, which leads to cost savings during production of heat exchanger 10 and also in its operation.

FIGS. 4a and 4b show a comparison of the qualitative temperature curve in a TEG heat exchanger having continuous ribbing (4a) or, as shown in FIG. 3a, in a TEG heat exchanger at an element-wise increment of the rib density in the flow direction, in the case of three TEG elements (4b).

FIG. 4a shows the uniform drop of hot side temperature TH in a thermoelectric generator as a function of the covered distance x of heat flow 40 in an heat exchanger having continuous ribbing. Furthermore, an admissible maximum temperature Tmax is drawn in, which limits hot side temperature TH at the intake. Temperature difference TH-TC drops off, and with that the efficiency of the continuously ribbed heat exchanger.

FIG. 4b shows the stepwise drop of hot side temperature TH in a thermoelectric generator as a function of the covered distance x of heat flow 40 in an heat exchanger having an element-wise increment in the ribbing. TH is also limited by the admissible maximum temperature Tmax.

The number of ribs 42 is increased according to the individual TEG rows 38.1, 38.2, 38.3, in order to increase the surface for the heat transfer and to raise the TEG hot side temperature TH, which leads to an enlarged temperature difference TH-TC. Whereas in the case of continuous ribbing, a deteriorated heat transfer on entire heat exchanger length 46 must be determined, in the case of adapted ribs 42, an increase in heat transfer is able to take place at rear end 44 of heat exchanger 10, and the entire heat output, and consequently the electrical output of the thermoelectric generators is able to be raised.

1-15. (canceled)

16. A heat exchanger for a thermoelectric generator, comprising:
a heat exchanger arrangement having at least two channels for a cooling medium and at least one channel for a heating medium;
wherein the at least one channel for the heating medium is equipped with ribs in the inner region.

17. The heat exchanger of claim 16, wherein the number of ribs increases in a heating flow direction.

18. The heat exchanger of claim 16, wherein an increase in the number of ribs occurs at an element-wise increment of the thermoelectric generator.

19. The heat exchanger of claim 16, wherein the channels for the cooling medium and the channel for the heating medium extend in planes that are parallel to one another, so as to form a stack having a stack axis and the channels for the cooling medium and the channel for the heating medium are situated along the stack axis in alternating fashion.

20. The heat exchanger of claim 16, wherein the heat exchanger has a heating medium supplied to it.

21. The heat exchanger of claim 16, wherein a cooling flow direction is in a direction counter to a heating flow direction.

22. The heat exchanger of claim 16, wherein at least one TEG row is located within the heat exchanger, the thermoelectric generators being mounted in the heating flow direction.

23. The heat exchanger of claim 16, wherein the thermoelectric generator is made of semiconductor materials.

24. The heat exchanger of claim 16, wherein a plurality of thermoelectric generators are mounted in parallel in the heat exchanger between the cooling medium and the heating medium.

25. The heat exchanger of claim 16, wherein a plurality of thermoelectric generators are mounted in series in the heat exchanger between the cooling medium and the heating medium.

26. The heat exchanger of claim 16, wherein a plurality of thermoelectric generators are mounted in parallel and in series in the heat exchanger between the cooling medium and the heating medium.

27. The heat exchanger of claim 16, wherein the ribs are configured as wavy ribs.

28. The heat exchanger of claim 16, wherein the ribs are configured as flat ribs.

29. The heat exchanger of claim 16, wherein the ribs on the inside of the channel for a heating medium reach from one side of the channel for a heating medium to an opposite side of the channel for a heating medium.

30. The heat exchanger of claim 16, wherein at least one rib is connected to the channel for a heating medium one of by a continuous material, by form locking, and by force locking.

31. The heat exchanger of claim 16, wherein the heat exchanger has a heating medium supplied to it, which originates from a waste heat system.

32. The heat exchanger of claim 16, wherein the heat exchanger has a heating medium supplied to it, which originates from a waste heat system and is the exhaust gas of an internal combustion engine of a motor vehicle.
